(19) United States
(12) Patent Application Publication
(10) Pub. No.: US 2021/0191220 A1
(43) Pub. Date: Jun. 24, 2021

(54) DISPLAY DEVICE SYSTEM AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Yanqiu Li, Beijing (CN); Liping Lei, Beijing (CN); Juan Yu, Beijing (CN)

(21) Appl. No.: 17/000,237

(22) Filed: Aug. 21, 2020

(30) Foreign Application Priority Data
Dec. 19, 2019 (CN) 201922296902.5

(51) Int. Cl. G02F 1/163; G02F 1/155; H01L 35/32

(52) U.S. Cl. CPC G02F 1/163; G02F 1/15165; H01L 35/32; G02F 1/155

(57) ABSTRACT

A display device system and a display device are disclosed. The display device system includes: a display device comprising an electrochromic pattern; a control circuit, one port of which is connected to the display device; a thermo-electric conversion film, one end of which is connected to the other port of the control circuit, and the other end of which is an end for connecting to an external electronic device; wherein the thermo-electric conversion film is configured to receive waste heat from the external electronic device and convert the waste heat to electrical energy for powering the control circuit, and the control circuit is configured to control change of the electrochromic pattern.

### CROSS-REFERENCE TO RELATED APPLICATION

This application claims the benefit of priority to Chinese Patent Application No. 201922296902.5, filed on Dec. 19, 2019, which is incorporated herein by reference in its entirety.

### TECHNICAL FIELD

The present disclosure relates to the technical field of electronic devices, particularly to a display device system and a display device.

### BACKGROUND

Electronic products produce a large amount of waste heat during use. In particular, recently developed MiniLED display screens produce a great amount of waste heat due to the large number of MiniLEDs. The direct dissipation of the heat from an electronic device will result in wasting of resources.

Therefore, how to utilize waste heat from an electronic device becomes an urgent problem to be solved.

### SUMMARY

The following technical solutions are mainly provided in the present disclosure.

In an aspect, embodiments of the present disclosure provide a display device system comprising:

a display device comprising an electrochromic pattern;

a control circuit, one port of which is connected to the display device; and

a thermo-electric conversion film, one end of which is connected to the other port of the control circuit, and the other end of which is an end for connecting to an external electronic device;

wherein the thermo-electric conversion film is configured to receive waste heat from the external electronic device and convert the waste heat to electrical energy for powering the control circuit, and the control circuit is configured to control change of the electrochromic pattern.

Optionally, the display device comprises a first part and a second part disposed with cells aligned with those of the first part;

wherein the first part comprises a first conductive film layer and an electrochromic layer on the first conductive film layer, the electrochromic layer comprising an electrochromic pattern region, and the second part comprises a second conductive film layer and a linking layer; the first part and the second part are disposed with cells aligned in such a manner that the electrochromic layer faces the linking layer;

the first conductive film layer and the second conductive film layer are respectively connected to the one port of the control circuit, and the other port of the control circuit is connected to the thermo-electric conversion film, such that the display device, the control circuit and the thermo-electric conversion film form a closed loop, and the electrochromic pattern changes depending on driving of the control circuit.

Optionally, the first part further comprises an insulating layer on a side of the electrochromic layer away from the first conductive film layer, wherein the insulating layer is hollowed out in the electrochromic pattern region.

Optionally, the first part and the second part are disposed with cells aligned in such a manner that the insulating layer faces the linking layer.

Optionally, the electrochromic pattern region is composed of a plurality of electrochromic pattern units;

at least one of the first conductive film layer and the second conductive film layer is composed of a plurality of conductive units each corresponding to one of the electrochromic pattern units and connected to the control circuit.

Optionally, any one of the conductive units in the first conductive film layer, the second conductive film layer, the control circuit and the thermo-electric conversion film form a set of closed loop, wherein the control circuit is configured to control a voltage of each set of closed loop, such that each of the electrochromic pattern units changes differently from others under an action of a different voltage of driving circuit.

Optionally, any one of the conductive units in the second conductive film layer, the first conductive film layer, the control circuit and the thermo-electric conversion film form a set of closed loop, wherein the control circuit is configured to control a voltage of each set of closed loop, such that each of the electrochromic pattern units changes differently from others under an action of a different voltage of driving circuit.

Optionally, the electrochromic pattern region is composed of a plurality of electrochromic pattern units, and each of the electrochromic pattern units is formed from one electrochromic material, such that different electrochromic pattern units change differently from each other under an action of driving circuit.

Optionally, the electrochromic layer is coincided with the electrochromic pattern region.

Optionally, the first part further comprises a first transparent substrate on which the first conductive film layer and the electrochromic layer are sequentially disposed; and the second part further comprises a second transparent substrate on which the second conductive film layer and the linking layer are sequentially disposed.

Optionally, the first transparent substrate and the second transparent substrate are glass substrates.

Optionally, an electrochromic material for forming the electrochromic pattern comprises an inorganic electrochromic material and an organic electrochromic material.

Optionally, the organic electrochromic material comprises a polyaniline-based, a polythiophene-based or a polypyrrole-based material.

Optionally, the thermo-electric conversion film comprises: a composite film of SiC and PEDOT:PSS, a composite film of PEDOT:PSS and SiC nanowires (SiC-NWs), a film of PEDOT:PSS and BNNSs (BN nanosheets), a composite film of PEDOT:PSS and (Ca₁₋ₓAgₓ)₃Co₄O₉, a heterostructure film of PEDOT:PSS and Ce—MoS₂, or an aerogel composite film of PEDOT:PSS and Te nanowires (PEDOT:PSS/Te-NWs).

Optionally, the linking layer is a conductive gel layer.

In another aspect, the present disclosure provides a display device for the display device system as described previously, comprising:

a first part comprising a first conductive film layer and an electrochromic layer on the first conductive film layer, wherein the electrochromic layer comprises an electrochromic pattern region, and the first conductive film layer is connected to a control circuit; and

a second part comprising a second conductive film layer and a linking layer, wherein the second conductive film layer is connected to the control circuit, and the second part and the first part are disposed with cells aligned in such a manner that the electrochromic layer faces the linking layer.

Optionally, the first part further comprises an insulating layer on a side of the electrochromic layer away from the first conductive film layer, wherein the insulating layer is hollowed out in the electrochromic pattern region.

Optionally, the electrochromic pattern region is composed of a plurality of electrochromic pattern units, and at least one of the first conductive film layer and the second conductive film layer is composed of a plurality of conductive units each corresponding to one of the electrochromic pattern units and connected to the control circuit.

Optionally, the electrochromic pattern region is composed of a plurality of electrochromic pattern units, and each of the electrochromic pattern units is formed from one electrochromic material, such that different electrochromic pattern units change differently from each other under an action of a driving circuit.

Optionally, the first part further comprises a first transparent substrate on which the first conductive film layer and the electrochromic layer are sequentially disposed; and the second part further comprises a second transparent substrate on which the second conductive film layer and the linking layer are sequentially disposed.

### BRIEF DESCRIPTION OF THE DRAWINGS

FIG. 1 shows a schematic structural diagram of a display device system provided in the present disclosure;

FIG. 2 shows a sectional view of a display device system provided in the present disclosure;

FIG. 3 shows a flow chart of the formation of a display device provided in the present disclosure;

FIG. 4 shows a flow chart of the formation of another display device provided in the present disclosure;

FIG. 5 is a schematic diagram of a display device system provided in an embodiment of the present disclosure in an unpowered state;

FIG. 6 is a schematic diagram of a display device system provided in an embodiment of the present disclosure in a powered state;

FIG. 7 is a schematic diagram of another display device system provided in an embodiment of the present disclosure in an unpowered state;

FIG. 8 is a schematic diagram of another display device system provided in an embodiment of the present disclosure in a powered state;

FIG. 9 is a schematic diagram of a thermo-electric conversion film provided in an embodiment of the present disclosure;

FIG. 10 is a schematic diagram of a display device provided in an embodiment of the present disclosure connected to an external electronic device; and

FIG. 11 is a schematic diagram of another display device provided in an embodiment of the present disclosure connected to an external electronic device.

### DETAILED DESCRIPTION

Particular implementations, structures, features and functions of the display device system and display device proposed according to the present disclosure will be described in detail with reference to the drawings and embodiments.

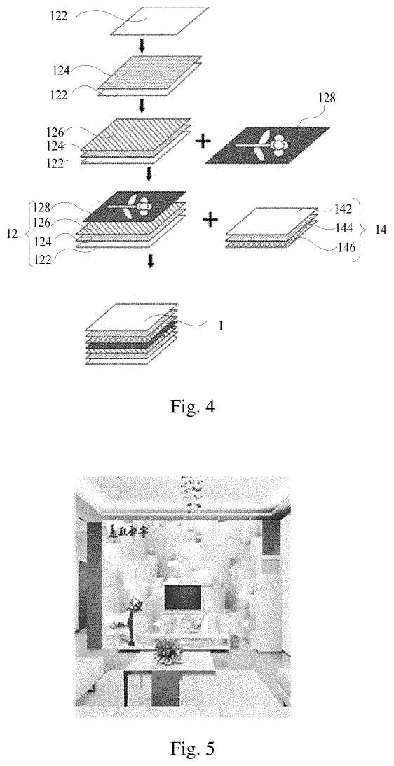

As shown in FIG. 1 to FIG. 11, the embodiments of the present disclosure provide a display device system 100 comprising:

a display device 1 comprising an electrochromic pattern;

a control circuit 2, one port of which is connected to the display device 1; and

a thermo-electric conversion film 3, one end of which is connected to the other port of the control circuit 2, and the other end of which is an end for connecting to an external electronic device 4;

wherein the thermo-electric conversion film 3 can receive waste heat from the external electronic device and convert the waste heat to electrical energy for powering the control circuit 2, such that the electrochromic pattern on the display device 1 is changed through the driving of the control circuit 2.

The display device system 100 provided in the present disclosure comprises a display device 1, a control circuit 2 and a thermo-electric conversion film 3, wherein the display device 1 has an electrochromic pattern changeable under an action of voltage. Electronic products in related art will produce a large amount of waste heat during use. The direct dissipation of the heat from an electronic device will result in wasting of resources. In the display device system 100 provided in the present disclosure, one end of the thermo-electric conversion film 3 is connected to the electronic device, for example, the thermo-electric conversion film 3 may be attached onto a heat generating portion of the electronic device, to receive a heat generated by the electronic device in use and to convert the heat into electrical energy. The other end of the thermo-electric conversion film 3 is connected to one port of the control circuit 2 through a lead wire, that is, the thermo-electric conversion film 3, which has received the heat from the external electronic device and converted the heat into the electrical energy, serves as a power supply for the entire display device system 100 for powering the display device system 100. Thus, the display device 1, the control circuit 2 and the thermo-electric conversion film 3 form a closed loop. The display device 1 has an electrochromic pattern, i.e., a pattern which can change under an action of voltage. The control circuit 2 powered by the thermo-electric conversion film 3 drives the display device 1, so that the electrochromic pattern on the display device 1 changes. As a result, the waste heat generated by the external electronic device is sufficiently utilized, and thus the energy resource is effectively utilized.

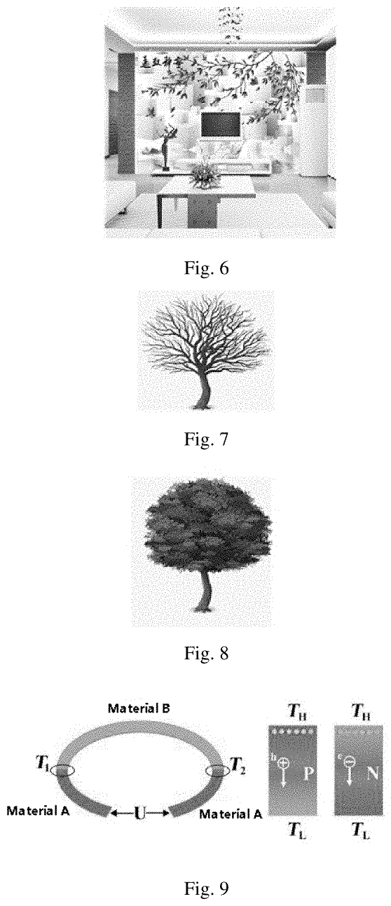

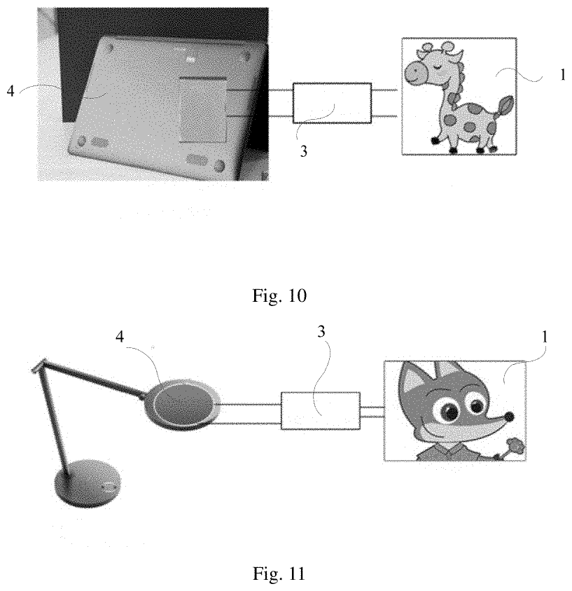

In the embodiments of the present disclosure, the thermo-electric conversion film has a flexible film structure. There is no need to reserve an interface on the external electronic device 4. As shown in FIG. 10 and FIG. 11, it is only required to attach the thermo-electric conversion film onto the external electronic device 4, without influencing the aesthetic appearance of the product. The thermo-electric conversion film may be attached to a heat generating position of any electronic product, and the shape and size of the thermo-electric conversion film are not limited and may be designed depending on the size of the electronic device. As shown in FIG. 5, the display device 1 has a blank pattern. Waste heat is generated after the use of the external electronic device 4. The thermo-electric conversion film 3 receives the heat and converts the heat into electrical energy, which is then transferred to the display device 1. Subsequently, as shown in FIG. 6, a reaction (such as an oxidation reaction) occurs on the electrochromic pattern of the display device 1 under an action of voltage and thus the electrochromic pattern changes to a pattern with leaves. As shown in FIG. 7, the pattern on the display device 1 is an autumn tree. The thermo-electric conversion film 3 receives waste heat generated after the use of the external electronic device 4 and converts the heat into an electrical energy, which is then transferred to the display device 1. Subsequently, as shown in FIG. 8, a reaction occurs on the electrochromic pattern of the display device 1 under an action of voltage and thus the pattern changes to a spring tree. This can improve the comfortability of home life and contribute to alleviating irritating mood. As such, the display device system 100 provided in the present disclosure can utilize the waste heat generated by an electronic device in use, thereby effectively utilizing energy resource and achieving the object of energy saving and environmental protection. Also, it can rapidly dissipate the heat of the external electronic device while utilizing the waste heat, thereby extending the lifetime of the electronic product.

The display device system 100 provided in the present disclosure may be an independent product. Although it is used in cooperation with the external electronic device 4, the display device system 100 needs not to be tied-in the external electronic device 4, which is beneficial for sales.

The present disclosure will be further described in detail below with reference to the drawings and embodiments.

As shown in FIG. 1 to FIG. 4, in some embodiments, the display device 1 comprises a first part 12 and a second part 14 disposed with cells aligned with those of the first part 12.

The first part 12 comprises a first conductive film layer 124 and an electrochromic layer 126 disposed on the first conductive film layer 124, the electrochromic layer 126 comprising an electrochromic pattern region; the second part 14 comprises a second conductive film layer 144 and a linking layer 146; and the first part 12 and the second part 14 are disposed with cells aligned in such a manner that the electrochromic layer 126 faces the linking layer 146.

The first conductive film layer 124 and the second conductive film layer 144 are respectively connected to one port of the control circuit 2, and the other port of the control circuit 2 is connected to the thermo-electric conversion film 3, such that the display device 1, the control circuit 2 and the thermo-electric conversion film 3 form a closed loop, and the electrochromic pattern changes depending on driving of the control circuit 2.

In the embodiments of the present disclosure, the electrochromic layer 126 comprises an electrochromic pattern region. In a powered state, an oxidation reaction occurs on the electrochromic pattern under an action of voltage, and the electrochromic pattern changes. In an unpowered state, a reduction reaction occurs on the electrochromic pattern, and the electrochromic pattern changes back to its original pattern. Thus, the control circuit 2 can control the electrochromic pattern region in the electrochromic film of the display device 1 through a voltage output, to realize the change of the electrochromic pattern, thereby accomplishing the utilization of the waste heat from the external electronic device 4.

In this embodiment, the first conductive film layer 124 may be a transparent conductive film layer of indium tin oxide semiconductor (ITO film layer), the second conductive film layer 144 may also be a transparent conductive film layer of indium tin oxide semiconductor (ITO film layer), and the linking layer 146 may be a conductive gel (ECHs) layer. The conductive gel layer has good adhesiveness and transparency, such that the display of pattern will not be influenced after the first part 12 and the second part 14 are disposed with cells aligned through the gel layer.

As shown in FIG. 1 to FIG. 4, in some embodiments, the first part 12 further comprises an insulating layer 128 disposed on a side of the electrochromic layer 126 away from the first conductive film layer 124, wherein the insulating layer 128 is hollowed out in the electrochromic pattern region.

In this embodiment, the first part 12 further comprises an insulating layer 128 disposed on the electrochromic layer 126, wherein the insulating layer 128 comprises a hollowed-out configuration in the electrochromic pattern region. Thereafter, the insulating layer 128 of the first part 12 and the linking layer 146 of the second part 14 are disposed with cells aligned, such that there is a current flow only in the hollowed-out region of the insulating layer 128, i.e., in the electrochromic pattern region, while there is no current flow in remaining regions covered by the insulating layer 128. As a result, a change of the electrochromic pattern is realized when the external electronic device 4 generates waste heat, thereby achieving the utilization of the waste heat from the external electronic device 4.

In the embodiments of the present disclosure, the electrochromic layer 126 may be coincided with the electrochromic pattern region.

In the embodiments of the present disclosure, when the electrochromic layer 126 is coincided with the electrochromic pattern region, that is, the electrochromic layer 126 is disposed only in a region corresponding to the electrochromic pattern on the first conductive film layer 124, and no electrochromic layer 126 is disposed in remaining regions, current flow can only be achieved in the electrochromic pattern region without disposing the insulating layer 128. Therefore, it is possible that no insulating layer 128 is disposed in the first part 12.

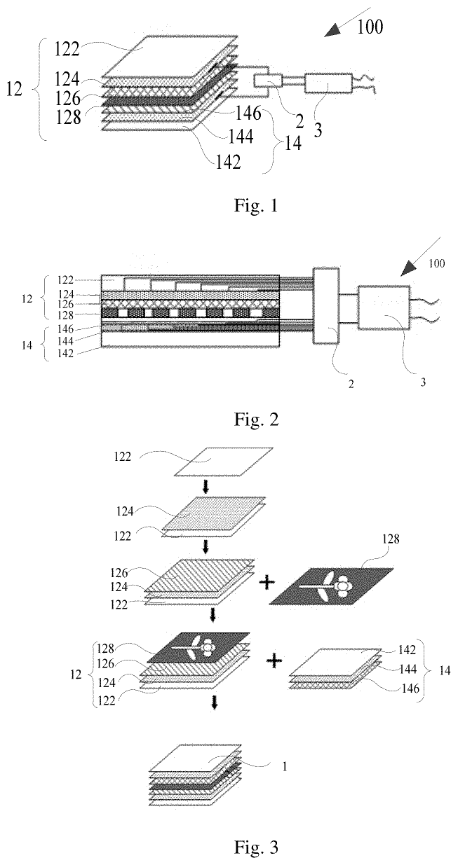

As shown in FIG. 1 to FIG. 2, in some specific embodiments, the electrochromic pattern region is composed of a plurality of electrochromic pattern units;

the first conductive film layer is composed of a plurality of first conductive units, and each of the electrochromic pattern units corresponds to one of the first conductive units; and/or

the second conductive film layer is composed of a plurality of second conductive units, and each of the electrochromic pattern units corresponds to one of the second conductive units;

the plurality of the first conductive units and/or the plurality of the second conductive units are respectively connected to the control circuit, wherein any one of the first conductive units, the second conductive film layer, the control circuit and the thermo-electric conversion film form a set of closed loop, or any one of the second conductive units, the first conductive film layer, the control circuit and the thermo-electric conversion film form a set of closed loop, and wherein the control circuit is configured to control a voltage of each set of closed loop, such that each of the electrochromic pattern units changes differently from others under an action of a different voltage of driving circuit.

In some embodiments of the present disclosure, the first conductive film layer 124 is composed of a plurality of first conductive units, the hollowed-out region of the insulating layer 128 corresponds to the electrochromic pattern region, the electrochromic pattern region is composed of a plurality of electrochromic pattern units and is formed from one electrochromic material, each of the electrochromic pattern unit corresponds to one of the first conductive units, and each of the first conductive units is connected to the control circuit, such that each of the first conductive units, the second conductive film layer, the control unit and the thermo-electric conversion film form a conductive loop. Thus, the control circuit 2 can control the electrochromic pattern unit corresponding to each first conductive unit through the voltage. The voltage is distributed from the control circuit 2 to each of the first conductive units, and the electrochromic pattern units each display different color changes depending on different voltages. As a result, each of the electrochromic pattern units changes differently from others depending on a different voltage, so that the respective electrochromic pattern units are controlled to display different colors, achieving precise control of each detail of the electrochromic pattern by the control circuit 2.

In some embodiments of the present disclosure, the second conductive film layer is composed of a plurality of second conductive units, the hollowed-out region of the insulating layer 128 corresponds to the electrochromic pattern region, the electrochromic pattern region is composed of a plurality of electrochromic pattern units and is formed from one electrochromic material, each of the electrochromic pattern units corresponds to one of the second conductive units, and each of the second conductive units is connected to the control circuit, such that each of the second conductive units, the first conductive film layer, the control unit and the thermo-electric conversion film form a conductive loop. Thus, the control circuit 2 can control the electrochromic pattern unit corresponding to each second conductive unit through the voltage. The voltage is distributed from the control circuit 2 to each of the second conductive units, and the electrochromic pattern units each display different color changes depending on different voltages. As a result, each of the electrochromic pattern units changes differently from others depending on a different voltage, so that the respective electrochromic pattern units are controlled to display different colors, achieving precise control of each detail of the electrochromic pattern by the control circuit 2.

In some embodiments of the present disclosure, the first conductive film layer 124 is composed of a plurality of first conductive units, the second conductive film layer is composed of a plurality of second conductive units, the hollowed-out region of the insulating layer 128 corresponds to the electrochromic pattern region, the electrochromic pattern region is composed of a plurality of electrochromic pattern units and is formed from one electrochromic material, each of the electrochromic pattern units corresponds to one of the first conductive units, and each of the first conductive units corresponds to one of the second conductive units, wherein each of the first conductive units, the second conductive unit corresponding to this first conductive unit, and the control unit form a conductive loop. Thus, the control circuit 2 can control the electrochromic pattern unit corresponding to each first conductive unit through the voltage. The voltage is distributed from the control circuit 2 to each of the first conductive units, and the electrochromic pattern units each display different color changes depending on different voltages. As a result, each of the electrochromic pattern units changes differently from others depending on a different voltage, so that the respective electrochromic pattern units are controlled to display different colors, achieving precise control of each detail of the electrochromic pattern by the control circuit 2.

In the embodiments of the present disclosure, the electrochromic pattern region is composed of a plurality of electrochromic pattern units, and each of the electrochromic pattern units may be formed from one electrochromic material, such that different electrochromic pattern units change differently from each other under an action of a driving circuit. The plurality of electrochromic pattern units may also be composed of different electrochromic materials, and different electrochromic materials have different color changes under an action of the same voltage. Thus, even if the same voltage is input, different electrochromic pattern units will display different colors. That is, by applying (for example, spray coating) different electrochromic materials, different pattern colors are achieved at different positions under the action of the same voltage applied to the electrochromic pattern. The number of the electrochromic pattern units is the same as the number of the colors of the electrochromic pattern. The technique of achieving different pattern changes under an action of the same voltage by spray coating different electrochromic materials is usually used in a pattern with a relatively low color requirement.

In the embodiments of the present disclosure, the control circuit 2 is not particularly limited, as long as it can control the first conductive film layer 124 and the second conductive film layer 144 respectively.

As shown in FIG. 1 to FIG. 4, in the embodiments, the first part 12 further comprises a first transparent substrate 122 on which the first conductive film layer 124 is disposed; and the second part 14 further comprises a second transparent substrate 142 on which the second conductive film layer 144 is disposed.

The first transparent substrate and the second transparent substrate may be glass substrates.

In one embodiment of the present disclosure, the first part 12 comprises a first glass substrate 122, a first conductive film layer 124, an electrochromic layer 126 and an insulating layer 128, wherein the first conductive film layer 124, the electrochromic layer 126 and the insulating layer 128 are sequentially disposed on the first glass substrate 122; and the second part 14 comprises a second glass substrate 142, a second conductive film layer 144 and a gel layer 146, wherein the second conductive film layer 144 and the gel layer 146 are sequentially disposed on the second glass substrate 142. The insulating layer 128 of the first part 12 is attached to the gel layer 146 of the second part 14 to achieve the cell alignment of the first part 12 and the second part 14. The first glass substrate 122 and the second glass substrate 142 are used for protecting the first conductive film layer 124, the electrochromic layer 126, the insulating layer 128 and the second conductive film layer 144.

In the embodiments of the present disclosure, the electrochromic material comprises an inorganic electrochromic material and an organic electrochromic material, and the organic electrochromic material may comprise a polyaniline-based, polythiophene-based and/or polypyrrole-based material.

In the embodiments, the types of electrochromic material are not limited, as long as they have a plenty of color changes and good stability. Commonly used electrochromic material comprises a polyaniline-based (PANI), polythiophene-based (PTh) and/or polypyrrole-based (PPy) material. Conductive polythiophene-based electrochromic material comprises polythiophene and derivatives thereof, which have color changes as shown in Table 1. Table 2 shows colors of some inorganic electrochromic materials in oxidation and reduction states. Table 3 shows colors of some organic electrochromic materials in oxidation and reduction states. Table 4 shows colors of compounds in some polymer electrochromic materials in oxidation and reduction states. Table 5 shows colors of monomers in some polymer electrochromic materials in oxidation and reduction states.

TABLE 1

| | Color | Color |
|---|---|---|
| Polymer | (reduction state) | (oxidation state) |
| Polythiophene (PTh) | Bright red | Light blue |
| Poly(3-methylthiophene) | Red | Deep blue |
| (PMeTh) | | |
| Poly(3-bromothiophene) | Deep red | Deep blue |
| (PBrTh) | | |
| Poly(3,4-dibromothiophene) | Red | Green or blue |
| (PDBrTh) | | |

TABLE 2

| | Color change | |
|---|---|---|
| Material | Oxidation state | Reduction state |
| WO₃ | Blue | Red |
| WO₃ (Au doped) | Blue | Red |
| Polytungstate | Blue | |
| Zr(WO₃) | Blue | |
| MoO₃ | Blue | Light green |
| V₂O₅ | Deep green | Yellow |
| Nb₂O₅ | Deep blue | |
| TiO₂ | Blue black | |
| IrOₓ, Ir(OH)ₓ | | Blue black |
| Cr₂O₃ | | Black |
| NiOₓ, Ni(OH)ₓ | | Deep blue |
| RhO₂ | Yellow/dark green | Brown/purple |
| CoOₓ | Purplish red/ | Gray black |
| | reddish brown | |
| InN | Yellow | Gray black |

TABLE 3

| | Color change | |
|---|---|---|
| Compound name | Reduction state | Oxidation state |
| Alkyl bipyridyl | Yellowish brown | Purple |
| Hexamethylbenzene (HMB) | Colorless | Red |
| Anthraquinone (AQ) | White | White |
| Tetrathiafulvalene (TTF) | Yellow | Bluish purple |
| Dimethylbenzidine (DMMA) | White | Red |
| Dimethyl phthalate (DMP) | White | Red |

TABLE 4

| | Color change | |
|---|---|---|
| Compound name | Reduction state | Oxidation state |
| Polypyrrole | Brown | Yellowish |
| Polythiophene | Blue | Tangerine |
| Polyaniline | Yellow | Bluish purple |

TABLE 5

| Monomer | Color change | |
|---|---|---|
| for polymer | Oxidation state | Reduction state |
| Polypyrrole | Bluish purple | Yellowish green |
| Polythiophene | Blue | Red |
| Polyaniline | Deep blue | Green |

In the embodiments of the present disclosure, the electrochromic material may comprise a conductive polypyrrole-based material. The conductive polypyrrole-based material has a blue grey color in a reduction state, and turns to a bright red color after oxidation.

In the embodiments of the present disclosure, the electrochromic material also comprises Prussian blue. Prussian blue is an electrochromic material having a property of several color changes. It has a dark blue color in a reduction state, and has a light green color in an oxidation state. Its general formula is M′ₖ[M″(CN)₆]ₜ, where k and l are integers, and M′ and M″ are ions with different valences of the same metal. For the Prussian blue system, M′ and M″ are two kinds of ions of Fe, Fe²⁺ and Fe³⁺. The color change reaction thereof is proposed as follows:

Fe2JFe₂+[Fe²⁺(CN)₆]+(e⁻)+(J⁺)→J₂Fe₂+[Fe₂+(CN)₆];

Fe³⁺₄[Fe²⁺(CN)₆]+(4e⁻)+(4J⁺)→Fe²⁺₄[Fe²⁺(CN)₆]₃;

wherein J⁺ is typically K⁺, the compound on the left side of the formula is Prussian blue, and the compounds on the right sides are known as Everitt salt and Prussian white respectively. Prussian blue is usually used together with WO₃ to form a complementary color change system.

The electrochromic material also comprises viologen, with a chemical name of 1,1′-bis(substituent)-4,4′-bipyridinium. It has three redox states, where in State A, it is in the form of divalent cation, which is colorless and the most stable; in State B, it is in the form of a monovalent cation and has a bluish purple color; and in State C, it is a neutral particle and has a deep red color. Each step of conversion will produce a different color, and the color change completely depends on the substituent group (—R). The monovalent cation is colored because there is a strong photo-electric transfer between molecules. When the substituent of alkyl is short, the ion exhibits a blue color, and exhibits a bluish purple color in a relatively concentrated solution. With increase in the chain length, the dimerization between molecules increases, and thus the color gradually turns to deep red.

The electrochromic material may also be iridium oxide (IrOₓ). IrOₓ has an electrochromic effect of changing from a transparent state to a blue black color, where one state corresponds to the extraction of H⁺, and the other state corresponds to the injection of OH⁻. The color change reaction thereof is as follows:

Ir(OH)₃−(H⁺)−(e⁻)→IrO₂.H₂O;

Ir(OH)₃+(OH⁻)+(e⁻)→IrO₂.H₂O.

The electrochromic material may also be rhodium oxide (Rh₂O₃). Rh₂O₃ has an electrochromic effect of changing from a yellow color to a dark green color or a puce color. The color change reaction thereof is as follows:

Rh₂O₃+(2OH⁻)+(2h⁺)→2RhO₂+H₂O.

The electrochromic material may also be phthalocyanine with a molecular formula abbreviated as MH(Pc)₂, where M is a lanthanide metal and Pc represents a divalent (C₃₂H₁₆N₈)²⁻. When the metal is trivalent, active hydrogen will remain in the complex. For example, the electrochromic characteristic of a LuH(Pc)₂ film is as follows: the color is red at +0.1 V, is green at 0 V, is blue at −0.8 V, and is purple at −1.2 V.

In the embodiments, when the electrochromic material is an inorganic material, complex technologies such as vacuum deposition and sputtering are needed in its preparation; the color change is limited to a few colors; the color contrast is moderate; the switch time is approximately between 10 ms and 750 ms; and the cycling number from power on to power off during its lifetime is between 10³ and 10⁵. When the electrochromic material is an organic polymer material, its preparation is simple, the material may be synthesized by an electrochemical polymerization method, the film may be prepared by simple dip coating or spray coating process; the color change depends on the doping percentage, the monomer selection and so on, so a number of variable colors can be obtained, and the color contrast is very high; the switch time is approximately between 10 ms and 120 ms; and the cycling number from power on to power off during its lifetime is between 10⁴ and 10⁶.

In the embodiments of the present disclosure, the thermo-electric conversion film 3 is a functional material which achieves a direct thermal energy-electrical energy mutual conversion by using directional movement of carriers inside a solid, the conversion from thermo energy to electrical energy being achieved mainly by using Seebeck effect. As shown in FIG. 9, for the Seebeck effect, in a closed loop formed from two materials, i.e., a conductor A and a conductor B, when two contact points are respectively at different temperatures, T1 (low temperature) and T2 (high temperature), an electromotive force (V) will be produced, and thus there will be a current in the loop. This is because when two different kinds of metals or semi-conductors are contacted with each other, difference in internal electron density therebetween will be eliminated through diffusion on the contact surface. Because the diffusion rate of electrons is proportional to the temperature of the contact area, continuous diffusion of electrons can be ensured as long as a temperature gradient is created between those two materials, and a potential difference, i.e., a voltage, will be formed between those two materials.

The Seebeck effect can also occur in the same material. As shown in FIG. 9, when two ends of one material are in different temperature environments respectively, the temperature difference between the two ends of the sample will cause uneven concentration distribution of its internal carriers, and at this time, the carriers on the high energy end with higher energy, i.e., the carriers at a position of the hot end, will diffuse to the low energy end, i.e., the cold end, to form an electric field in its interior, producing a current. The electromotive force producing such a current is referred to as a thermoelectromotive force, and this phenomenon is referred to as the Seebeck effect. The magnitude of the thermoelectromotive force is proportional to the temperature difference between the two contact points of the sample ΔT=(ΔT=T2−T1) as follows:

ΔV=S_{AB}·ΔT;

where in the formula, S_{AB} is the Seebeck coefficient of a material, with a unit of V/K. In general, when a current flows from a low temperature end to a high temperature end of a semiconductor, the Seebeck coefficient is positive, indicating that the material is a P-type material. Otherwise, the material is an N-type material, and the Seebeck coefficient is negative. A conversion from thermal energy to electrical energy can be achieved by using the Seebeck effect.

In the embodiments of the present disclosure, the thermo-electric conversion film 3 may be a composite film of SiC and PEDOT:PSS, a composite film of PEDOT:PSS and SiC-NWs, a film of PEDOT:PSS and BNNSs, a composite film of PEDOT:PSS and (Ca₁₋ₓAgₓ)₃Co₄O₉, a heterostructure composite film of PEDOT:PSS and Ce—MoS₂, or an aerogel composite film of PEDOT:PSS and Te nanowires (PEDOT:PSS/Te-NWs).

As shown in FIG. 1 to FIG. 4, in another aspect, the present application provides a display device 1 for the display device system 100 as described previously, comprising:

a first part 12 comprising a first conductive film layer 124 and an electrochromic layer 126 disposed on the first conductive film layer 124, wherein the electrochromic layer 126 comprises an electrochromic pattern region, and the first conductive film layer 124 is connected to a control circuit 2; and

a second part 14 disposed with cells aligned with those of the first part 12, comprising a second conductive film layer 144 and a linking layer 146, wherein the second conductive film layer 144 is connected to the control circuit 2;

wherein the first part 12 and the second part 14 are disposed with cells aligned in such a manner that the electrochromic layer 126 faces the linking layer 146.

In the embodiments, the display device 1 comprises a first part 12 and a second part 14, which are disposed with cells aligned to form the display device 1, wherein the first part 12 comprises a first conductive film layer 124 and an electrochromic layer 126 disposed on the first conductive film layer 124, and the second part 14 comprises a second conductive film layer 144 and a linking layer 146. The electrochromic layer 126 of the first part 12 and the linking layer 146 of the second part 14 are connected with cells aligned to achieve the cell alignment of the first part 12 and the second part 14. The first conductive film layer 124 and the second conductive film layer 144 are respectively connected to one port of the control circuit 2. The display device 1, the control circuit 2 and the thermo-electric conversion film 3 form a closed loop by connecting the first conductive film layer 124 and the second conductive film layer 144 to the control circuit 2 respectively, such that the display device 1 is controlled by the control circuit 2. The electrochromic layer 126 comprises an electrochromic pattern region. In a powered state, an oxidation reaction occurs on the electrochromic pattern under an action of voltage, and the electrochromic pattern changes. In an unpowered state, a reduction reaction occurs on the electrochromic pattern, and the electrochromic pattern changes back to its original pattern. Thus, the control circuit 2 can control the electrochromic pattern region in the electrochromic film of the display device 1 through a voltage output, to realize the change of the electrochromic pattern, thereby achieving the utilization of the waste heat from the external electronic device 4.

In some embodiments of the present disclosure, the first part 12 comprises a first glass substrate 122, a first conductive film layer 124, an electrochromic layer 126 and an insulating layer 128, wherein the first conductive film layer 124, the electrochromic layer 126 and the insulating layer 128 are sequentially disposed on the first glass substrate 122; and the second part 14 comprises a second glass substrate 142, a second conductive film layer 144 and a gel layer (a linking layer) 146, wherein the second conductive film layer 144 and the gel layer 146 are sequentially disposed on the second glass substrate 142. The insulating layer 128 of the first part 12 and the gel layer 146 of the second part 14 are aligned to achieve the cell alignment of the first part 12 and the second part 14. The first glass substrate 122 and the second glass substrate 142 are used for protecting the first conductive film layer 124, the electrochromic layer 126, the insulating layer 128 and the second conductive film layer 144. The gel layer 146 has good adhesiveness and transparency, such that the first part 12 and the second part 14 can be disposed with cells aligned, without influencing the pattern.

The embodiments of the present disclosure provide a display device system and a display device. The display device system comprises a display device, a control circuit and a thermo-electric conversion film, wherein the display device has an electrochromic pattern, and the electrochromic pattern can change under an action of voltage. Electronic products in related art will produce a large amount of waste heat during use. The direct dissipation of the heat from an electronic device will result in wasting of resources. In the display device system provided in the present disclosure, one end of the thermo-electric conversion film is connected to the electronic device, for example, the thermo-electric conversion film may be attached onto a heat generating portion of the electronic device, to receive a heat generated by the electronic device in use and to convert the heat into electrical energy. The other end of the thermo-electric conversion film is connected to one port of the control circuit through a lead wire, that is, the thermo-electric conversion film, which has received the heat from the external electronic device and converted the heat into the electrical energy, serves as a power supply for powering the entire display device. Thus, the display device, the control circuit and the thermo-electric conversion film form a closed loop. The display device has an electrochromic pattern, i.e., a pattern which can change under an action of voltage. The control circuit powered by the thermo-electric conversion film drives the display device, so that the display device can change its pattern through the action of the waste heat from the electronic device. Therefore, the display device system provided in the present disclosure can utilize the waste heat generated by an electronic device in use, thereby effectively utilizing the energy resource.

The above descriptions are only some particular embodiments of the present application, but the protection scope of the present application is not limited thereto. Within the technical scope disclosed in the present application, one skilled in the art can readily envisage variations and alternatives, and all of them are covered by the protection scope of the present application. Therefore, the protection scope of the present application should be defined by the claims only.

What is claimed is:

1. A display device system comprising:
a display device comprising an electrochromic pattern;
a control circuit, a first port of which is connected to the display device; and
a thermo-electric conversion film, a first end of which is connected to a second port of the control circuit, and a second end of which is an end for connecting to an external electronic device;
wherein the thermo-electric conversion film is configured to receive waste heat from the external electronic device and convert the waste heat to electrical energy for powering the control circuit, and the control circuit is configured to control change of the electrochromic pattern.

2. The display device system according to claim 1, wherein:
the display device comprises a first part and a second part disposed with cells aligned with those of the first part;
the first part of the display device comprises a first conductive film layer and an electrochromic layer on the first conductive film layer, the electrochromic layer comprising an electrochromic pattern region, and the second part of the display device comprises a second conductive film layer and a linking layer;
the first part of the display device and the second part of the display device are disposed with cells aligned in such a manner that the electrochromic layer faces the linking layer; and
the first conductive film layer and the second conductive film layer are respectively connected to the first port of the control circuit, and the second port of the control circuit is connected to the thermo-electric conversion film, such that the display device, the control circuit and the thermo-electric conversion film form a closed loop, and the electrochromic pattern changes depending on driving of the control circuit.

3. The display device system according to claim 2, wherein the first part of the display device further comprises an insulating layer on a side of the electrochromic layer away from the first conductive film layer, wherein the insulating layer is hollowed out in the electrochromic pattern region.

4. The display device system according to claim 3, wherein the first part of the display device and the second part of the display device are disposed with cells aligned in such a manner that the insulating layer faces the linking layer.

5. The display device system according to claim 2, wherein:
the electrochromic pattern region is composed of a plurality of electrochromic pattern units;
at least one of the first conductive film layer and the second conductive film layer is composed of a plurality of conductive units each corresponding to one of the electrochromic pattern units and connected to the control circuit.

6. The display device system according to claim 5, wherein:
any one of the conductive units in the first conductive film layer, the second conductive film layer, the control circuit and the thermo-electric conversion film form a set of closed loop, wherein the control circuit is configured to control a voltage of each set of closed loop, such that each of the electrochromic pattern units changes differently from others under an action of a different voltage of driving circuit.

7. The display device system according to claim 5, wherein:
any one of the conductive units in the second conductive film layer, the first conductive film layer, the control circuit and the thermo-electric conversion film form a set of closed loop, wherein the control circuit is configured to control a voltage of each set of closed loop, such that each of the electrochromic pattern units changes differently from others under an action of a different voltage of driving circuit.

8. The display device system according to claim 2, wherein:
the electrochromic pattern region is composed of a plurality of electrochromic pattern units, and each of the electrochromic pattern units is formed from one electrochromic material, such that different electrochromic pattern units change differently from each other under an action of driving circuit.

9. The display device system according to claim 2, wherein:
the electrochromic layer is coincided with the electrochromic pattern region.

10. The display device system according to claim 2, wherein:
the first part of the display device further comprises a first transparent substrate on which the first conductive film layer and the electrochromic layer are sequentially disposed; and
the second part of the display device further comprises a second transparent substrate on which the second conductive film layer and the linking layer are sequentially disposed.

11. The display device system according to claim 10, wherein:
the first transparent substrate and the second transparent substrate are glass substrates.

12. The display device system according to claim 1, wherein:
an electrochromic material for forming the electrochromic pattern comprises an inorganic electrochromic material and an organic electrochromic material.

13. The display device system according to claim 12, wherein:
the organic electrochromic material comprises a polyaniline-based, a polythiophene-based or a polypyrrole-based material.

14. The display device system according to claim 1, wherein the thermo-electric conversion film comprises:
a composite film of SiC and PEDOT:PSS, a composite film of PEDOT:PSS and SiC-NWs, a film of PEDOT:PSS and BNNSs, a composite film of PEDOT:PSS and (Ca₁₋ₓAgₓ)₃Co₄O₉, a heterostructure film of PEDOT:PSS and Ce—MoS₂, or an aerogel composite film of PEDOT:PSS and Te nanowires (PEDOT:PSS/Te-NWs).

15. The display device system according to claim 1, wherein:
the linking layer is a conductive gel layer.

16. A display device for the display device system according to claim 1, comprising:
a first part comprising a first conductive film layer and an electrochromic layer on the first conductive film layer, wherein the electrochromic layer comprises an electrochromic pattern region, and the first conductive film layer is connected to a control circuit; and
a second part comprising a second conductive film layer and a linking layer, wherein the second conductive film layer is connected to the control circuit, and the second part and the first part are disposed with cells aligned in such a manner that the electrochromic layer faces the linking layer.

17. The display device according to claim 16, wherein:
the first part further comprises an insulating layer on a side of the electrochromic layer away from the first conductive film layer, wherein the insulating layer is hollowed out in the electrochromic pattern region.

18. The display device according to claim 16, wherein:
the electrochromic pattern region is composed of a plurality of electrochromic pattern units, and at least one of the first conductive film layer and the second conductive film layer is composed of a plurality of conductive units each corresponding to one of the electrochromic pattern units and connected to the control circuit.

19. The display device according to claim 16, wherein:
the electrochromic pattern region is composed of a plurality of electrochromic pattern units, and each of the electrochromic pattern units is formed from one electrochromic material, such that different electrochromic pattern units change differently from each other under an action of a driving circuit.

20. The display device according to claim 16, wherein:
the first part further comprises a first transparent substrate on which the first conductive film layer and the electrochromic layer are sequentially disposed; and
the second part further comprises a second transparent substrate on which the second conductive film layer and the linking layer are sequentially disposed.
